(19) United States
(12) Patent Application Publication
(10) Pub. No.: US 2019/0319038 A1
(43) Pub. Date: Oct. 17, 2019

(54) SEMICONDUCTOR DEVICES

(71) Applicant: Samsung Electronics Co., Ltd., Suwon-si (KR)

(72) Inventor: Gang Zhang, Suwon-si (KR)

(21) Appl. No.: 16/201,337

(22) Filed: Nov. 27, 2018

(30) Foreign Application Priority Data
Apr. 11, 2018 (KR) 10-2018-0042018

(51) Int. Cl. H01L 27/11575; H01L 27/11524; H01L 27/11556; H01L 27/11529; H01L 27/11548; H01L 27/1157; H01L 27/11582; H01L 27/11573; H01L 23/535

(52) U.S. Cl. CPC H01L 27/11575; H01L 27/11524; H01L 27/11556; H01L 27/11529; H01L 23/535; H01L 27/1157; H01L 27/11582; H01L 27/11573; H01L 27/11548

(57) ABSTRACT

A semiconductor device includes a peripheral circuit region on a first substrate, and including at least one circuit device, a memory cell region on a second substrate, on the first substrate, and including memory cells, and a through wiring region including a conductive region that passes through the memory cells and is on the second substrate, and a through contact plug that passes through the conductive region and the second substrate and is configured to electrically connect the memory cell region to the at least one circuit device.

### CROSS-REFERENCE TO RELATED APPLICATION

This application claims the benefit of priority under 35 U.S.C. § 119 to Korean Patent Application No. 10-2018-0042018, filed on Apr. 11, 2018, in the Korean Intellectual Property Office, the entire contents of which are incorporated herein by reference.

### BACKGROUND

### Field

The present inventive concepts relate to semiconductor devices and methods of creating the same.

### Description of Related Art

Semiconductor devices which have a smaller volume while performing high-capacity data processing are increasingly in demand. To create a semiconductor device having these preferred characteristics, the degree of integration of semiconductor elements forming such a semiconductor device may be increased. As a method for improving the degree of integration of the semiconductor device, a semiconductor device including gate electrodes stacked in a vertical direction has been developed. In such a semiconductor device, the number of stacked gate electrodes may be increased to achieve the high integration of the semiconductor device.

### SUMMARY

An aspect of the present inventive concepts is to provide a semiconductor device having improved reliability.

According to an aspect of the present inventive concepts, a semiconductor device includes: a peripheral circuit region provided on a first substrate, and including at least one circuit device, a memory cell region on a second substrate, on the first substrate, and including memory cells, and a through wiring region including a conductive region that passes through the memory cells and is on the second substrate, and a through contact plug that passes through the conductive region and the second substrate and is configured to electrically connect the memory cell region to the at least one circuit device.

According to an aspect of the present inventive concepts, a semiconductor device includes: a peripheral circuit region on a first substrate, and including at least one circuit device; a memory cell region on a second substrate that is on the first substrate, and including gate electrodes spaced apart from each other and stacked perpendicularly to an upper surface of the second substrate, and channels passing through the gate electrodes that extend in a first direction that is perpendicular to the upper surface of the second substrate; and a through wiring region including a conductive region passing through the gate electrodes and connected to the second substrate, and a through contact plug passing through the conductive region and through the second substrate and extending in the first direction.

According to an aspect of the present inventive concepts, a semiconductor device includes: a first region on a first substrate, and including at least one first device; a second region on a second substrate that is on the first substrate, and including second devices on the second substrate; and a through wiring region including a through wiring structure passing through the second substrate and electrically connecting the at least one first device to the second devices and a conductive region surrounding the through wiring structure.

### BRIEF DESCRIPTION OF DRAWINGS

The above and other aspects, features and other advantages of the present disclosure will be more clearly understood from the following detailed description, taken in conjunction with the accompanying drawings, in which:

FIG. 1 is a schematic block diagram of a semiconductor device according to example embodiments of the inventive concepts;

FIG. 2 is an equivalent circuit diagram of a cell array of a semiconductor device according to example embodiments of the inventive concepts;

FIG. 3 is a schematic perspective view illustrating a memory cell array and a peripheral circuit of a semiconductor device according to example embodiments of the inventive concepts;

FIG. 4 is a schematic layout view illustrating the arrangement of a semiconductor device according to example embodiments of the inventive concepts;

FIG. 5 is a schematic plan view of a semiconductor device according to example embodiments of the inventive concepts;

FIG. 6 is a schematic cross-sectional view of a semiconductor device according to example embodiments of the inventive concepts, and FIG. 6 illustrates a cross section taken along line I-I′ of FIG. 5;

FIGS. 7A and 7B are schematic plan views of a semiconductor device according to example embodiments of the inventive concepts;

FIG. 8 is a schematic cross-sectional view of a semiconductor device according to example embodiments of the inventive concepts;

FIG. 9 is a schematic cross-sectional view of a semiconductor device according to example embodiments of the inventive concepts;

FIG. 10 is a schematic cross-sectional view of a semiconductor device according to example embodiments of the inventive concepts; and

FIGS. 11A to 11O are schematic cross-sectional views illustrating a method for manufacturing a semiconductor device according to example embodiments of the inventive concepts.

### DETAILED DESCRIPTION

Hereinafter, example embodiments of the present disclosure will be described in detail with reference to the accompanying drawings.

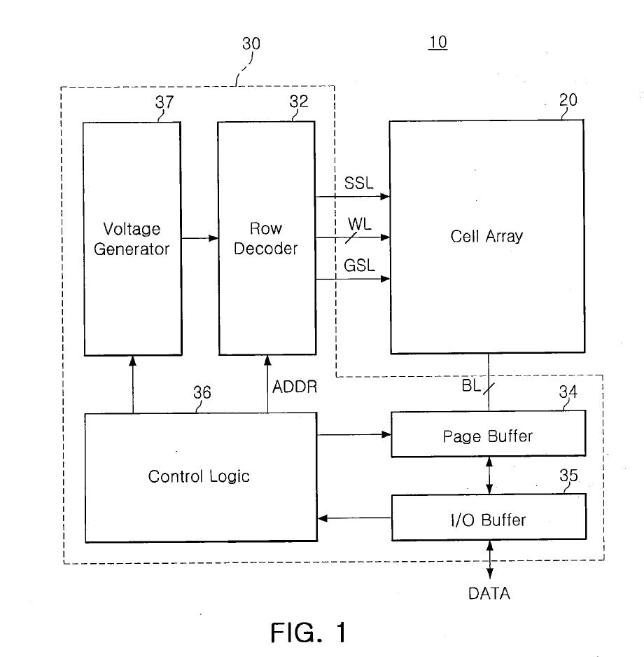

FIG. 1 is a schematic block diagram of a semiconductor device according to example embodiments of the inventive concepts.

Referring to FIG. 1, a semiconductor device 10 may include a memory cell array 20 and a peripheral circuit 30. The peripheral circuit 30 may include a row decoder 32, a page buffer 34, an input and output buffer 35, a control logic 36, and a voltage generator 37.

The memory cell array 20 may include a plurality of memory blocks, which may respectively include a plurality of memory cells. The plurality of memory cells may be connected to the row decoder 32 through a string selection line SSL, word lines WL, and a ground selection line GSL, and may be connected to the page buffer 34 through bit lines BL. In example embodiments, a plurality of memory cells, arranged in a single row, may be connected to a common word line WL, while a plurality of memory cells, arranged in a single column, may be connected to a common bit line BL.

The row decoder 32 may decode address ADDR, having been input, to generate and transmit driving signals of a word line WL. The row decoder 32 may provide a word line voltage, generated from the voltage generator 37, to each of a selected word line WL and non-selected word lines WL in response to the control of the control logic 36.

The page buffer 34 is connected to the memory cell array 20 through the bit lines BL, and may read data stored in the memory cells. The page buffer 34 may temporarily store data which is to be stored in the memory cells, or may detect data which is stored in the memory cells, depending on a mode of operation. The page buffer 34 may include a column decoder and a sense amplifier. The column decoder may selectively activate bit lines BL of the memory cell array 20, while the sense amplifier may sense a voltage of a bit line BL having been selected by the column decoder, and may read data stored in a memory cell, having been selected, during a reading operation.

The input and output buffer 35 may receive data DATA and transmit the data to the page buffer 34 during a programming operation, and may output the data DATA transmitted from the page buffer 34, externally, during a reading operation. The input and output buffer 35 may transmit the address or command having been input to the control logic 36.

The control logic 36 may control operations of the row decoder 32 and the page buffer 34. The control logic 36 may receive a control signal and an external voltage transmitted from an outside source, and may be operated according to the control signal having been received. The control logic 36 may control reading, writing, and/or erasing operations in response to the control signals.

The voltage generator 37 may generate voltages required for an internal operation using an external voltage, for example, a programming voltage, a reading voltage, an erasing voltage, and the like. The voltage generated by the voltage generator 37 may be transmitted to the memory cell array 20 by the row decoder 32.

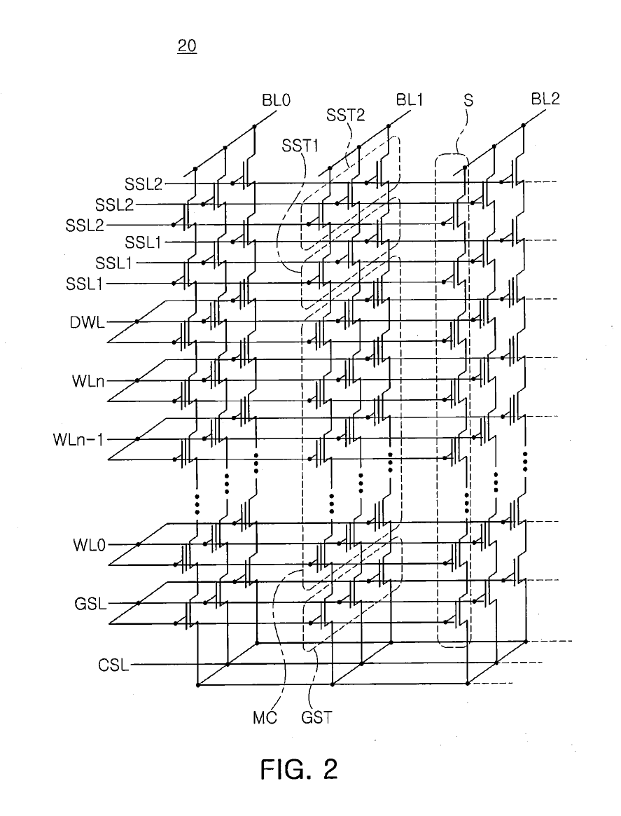

FIG. 2 is an equivalent circuit diagram of a cell array of a semiconductor device according to example embodiments of the inventive concepts.

Referring to FIG. 2, the memory cell array 20 may include memory cells MC, connected to each other in series, and a plurality of memory cell strings S, having a ground selection transistor GST as well as string selection transistors SST1 and SST2 connected in series at both ends of the memory cells MC. The plurality of memory cell strings S may be connected to respective bit lines BL0 to BL2 in parallel. The plurality of memory cell strings S may be connected to a common source line CSL in common. In other words, a plurality of memory cell strings S may be arranged between a plurality of bit lines BL0 to BL2 and a single common source line CSL. In an example embodiment, the common source line CSL may be provided as a plurality of common source lines, arranged two-dimensionally.

The memory cells MC connected to each other in series may be controlled by the word lines WL0 to WLn for selecting the memory cells MC. Respective memory cells MC may include a data storage element. Gate electrodes of the memory cells MC arranged at substantially the same distance from the common source line CSL may be connected to one of the word lines WL0 to WLn in common and may be in an equipotential state. In some embodiments, even when gate electrodes of the memory cells MC are arranged at substantially the same distance from the common source lines CSL, gate electrodes disposed in different rows or columns may be independently controlled.

The ground selection transistor GST may be controlled by the ground selection line GSL, and may be connected to the common source line CSL. The string selection transistors SST1 and SST2 may be controlled by string selection lines SSL1 and SSL2, respectively, and may be connected to the bit lines BL0 to BL2. In FIG. 2, a structure in which a single ground selection transistor GST and two string selection transistors SST1 and SST2 are connected to each of a plurality of memory cells MC connected to each other in series is illustrated. However, one of the string selection transistors SST1 and SST2 may be connected thereto, or a plurality of ground selection transistors GST may be connected thereto. One or more dummy lines DWL or buffer lines may be further arranged between an uppermost word line WLn among the word lines WL0 to WLn and the string selection lines SSL1 and SSL2, though the present inventive concepts are not limited thereto. In an example embodiment, one or more dummy lines DWL may be arranged between a lowermost word line WL0 and a ground selection line GSL.

When a signal is applied to the string selection transistors SST1 and SST2 through the string selection lines SSL1 and SSL2, a signal applied through the bit lines BL0 to BL2 is transmitted to the memory cells MC connected to each other in series, so data reading and writing operations may be executed. Moreover, a predetermined erasing voltage may be applied through a substrate, so an erasing operation for erasing data written to the memory cells MC may be executed. In an example embodiment, the memory cell array 20 may include at least one dummy memory cell string electrically isolated from the bit lines BL0 to BL2.

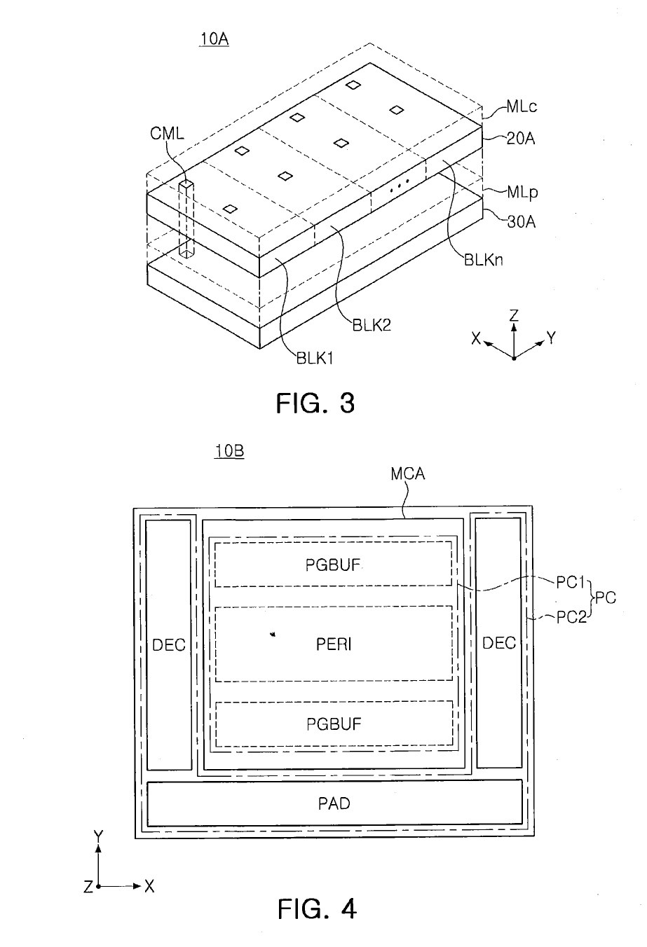

FIG. 3 is a schematic perspective view illustrating a memory cell array and a peripheral circuit of a semiconductor device according to example embodiments of the inventive concepts.

Referring to FIG. 3, a semiconductor device 10A may include a cell region semiconductor layer 20A, a peripheral circuit semiconductor layer 30A, a cell region metal layer MLc, and a peripheral circuit metal layer MLp. The cell region semiconductor layer 20A and the peripheral circuit semiconductor layer 30A may be disposed to be stacked in a vertical direction, for example, a z direction.

The cell region semiconductor layer 20A may be a layer in which word lines WL and bit lines BL forming the memory cell array 20 of FIG. 1 are formed on a substrate. The cell region semiconductor layer 20A may include memory blocks BLK1 to BLKn, having a three-dimensional structure or a vertical structure. For example, the memory blocks BLK1 to BLKn may form a structure stacked in a z direction on a plane extended in an x direction and a y direction. Respective memory blocks BLK1 to BLKn may include a plurality of strings extended in a z direction.

The peripheral circuit semiconductor layer 30A may be disposed below (e.g., in the z direction) the cell region semiconductor layer 20A. The peripheral circuit semiconductor layer 30A may be a layer in which circuits forming the peripheral circuit 30 of FIG. 1, for example, circuits corresponding to the row decoder 32, the page buffer 34, the control logic 36, and the like, are formed on a substrate.

The cell region semiconductor layer 20A and the peripheral circuit semiconductor layer 30A may be connected to metal layers MLc and MLp located thereabove, respectively. The cell region metal layer MLc may be formed on the cell region semiconductor layer 20A, and may include a plurality of cell wirings. The peripheral region metal layer MLp may be formed on the peripheral circuit semiconductor layer 30A, and may include a plurality of peripheral circuit wirings.

The cell region metal layer MLc and the peripheral region metal layer MLp may be connected to each other through the connecting metal layer CML. The connecting metal layer CML may extend from the cell region metal layer MLc, pass through the cell region semiconductor layer 20A, and may be connected to the peripheral region metal layer MLp. The arrangement of the connecting metal layer CML, illustrated in FIG. 3, may be variously changed in example embodiments.

FIG. 4 is a schematic layout view illustrating the arrangement of a semiconductor device according to example embodiments of the inventive concepts.

Referring to FIG. 4, a semiconductor device 10B may include a peripheral circuit region PC including various peripheral circuits DEC, PGBUF, PERI, and PAD, as well as a memory cell region MCA disposed on a portion of the peripheral circuit region PC. The peripheral circuit region PC may include a first peripheral circuit PC1 disposed below a memory cell region MCA and a second peripheral circuit PC2 disposed around the first peripheral circuit PC1.

The first peripheral circuit PC1 may include a page buffer PGBUF and other peripheral circuits PERI, while the second peripheral circuit PC2 may include a row decoder DEC and a pad circuit PAD. Other peripheral circuits PERI may include, for example, a latch circuit, a cache circuit, and/or a sense amplifier. The pad circuit PAD may include an electrostatic discharge (ESD) device or a data input and output circuit. However, in example embodiments, circuits included in each of the first peripheral circuit PC1 and the second peripheral circuit PC2 may be varied, so circuits disposed below the memory cell region MCA may be also varied.

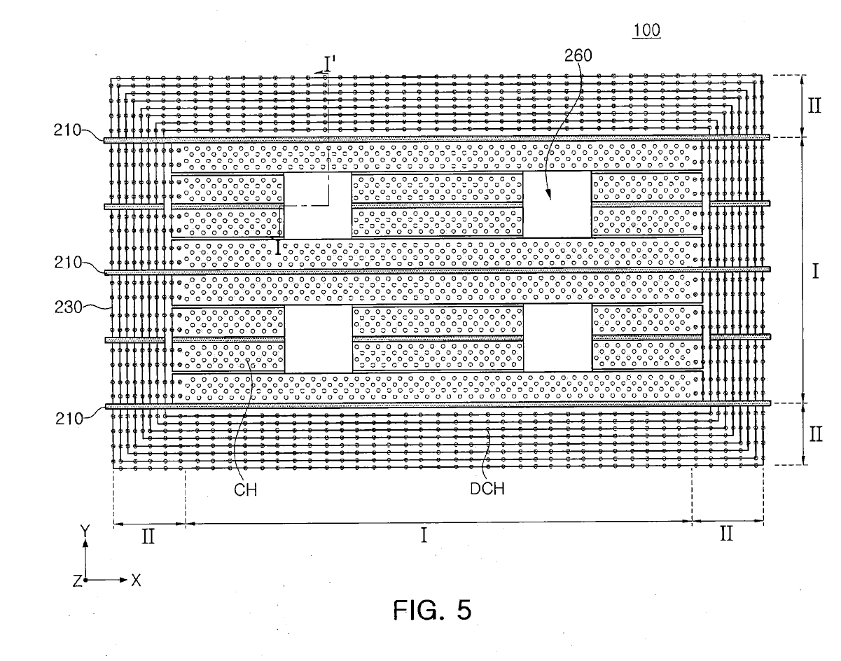

FIG. 5 is a schematic plan view of a semiconductor device according to example embodiments of the inventive concepts.

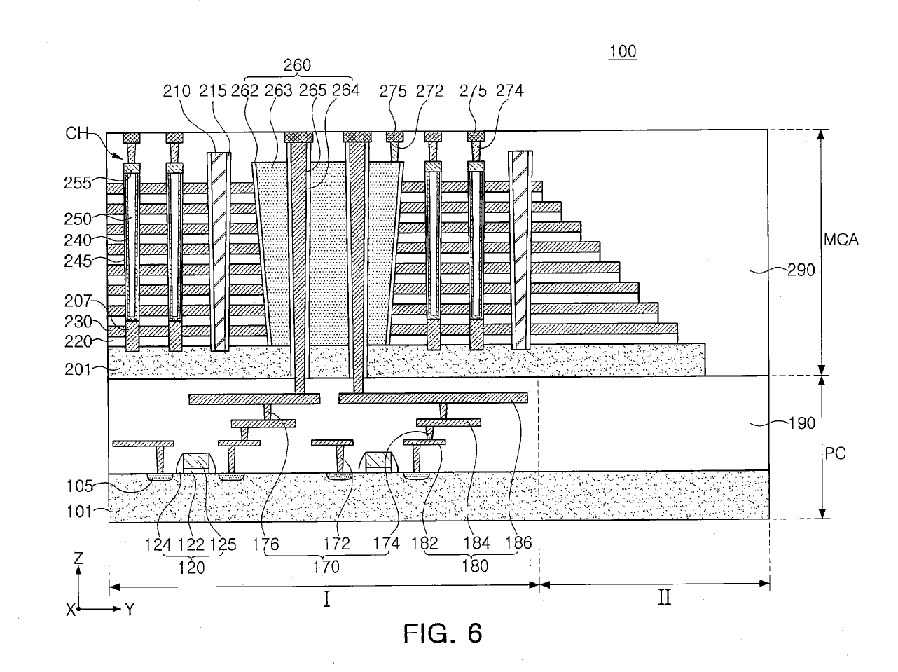

FIG. 6 is a schematic cross-sectional view of a semiconductor device according to example embodiments of the inventive concepts. FIG. 6 illustrates a cross section taken along line I-I′ of FIG. 5.

Referring to FIGS. 5 and 6, a semiconductor device 100 may include a first substrate 101 and a second substrate 201 disposed above (e.g., in a z direction) the first substrate 101. A peripheral circuit region PC is provided on the first substrate 101, and a memory cell region MCA is provided on the second substrate 201.

The peripheral circuit region PC may include the first substrate 101, circuit devices 120 disposed on the first substrate 101, a peripheral region insulating layer 190 on (e.g., covering) the circuit devices 120, lower contact plugs 170, and/or lower wiring lines 180.

The first substrate 101 may have an upper surface, extended in an x direction and a y direction. The first substrate 101 may include a semiconductor material, for example, a group IV semiconductor, a group III-V compound semiconductor, or a group II-VI oxide semiconductor. For example, the group IV semiconductor may include silicon, germanium, or silicon-germanium. The first substrate 101 may be provided as a bulk wafer or an epitaxial layer. The first substrate 101 may include well regions and device isolation regions including impurities.

The circuit devices 120 may include a circuit gate dielectric layer 122, a circuit gate electrode layer 125, and a spacer layer 124. An impurity region 105 may be disposed in the first substrate 101 adjacent sides of the circuit gate electrode layer 125. The circuit gate dielectric layer 122 may include silicon oxide, while the circuit gate electrode layer 125 may include a conductive material such as a metal, polycrystalline silicon, and/or metal silicide. The spacer layer 124 may be disposed on sidewalls of the circuit gate dielectric layer 122 and the circuit gate electrode layer 125, and may include, for example, silicon nitride.

The peripheral region insulating layer 190 may be on (e.g., cover) the first substrate 101 and the circuit devices 120 on the first substrate 101, and may be disposed between the first substrate 101 and the second substrate 201. The peripheral region insulating layer 190 may be formed of an insulating material.

The lower contact plugs 170 and the lower wiring lines 180 may form a lower wiring structure electrically connected to the circuit devices 120 in the peripheral circuit region PC. At least a portion of the lower contact plugs 170 and the lower wiring lines 180 may allow the circuit devices 120 to be electrically connected to the memory cell region MCA. The lower contact plugs 170 may include first lower contact plugs 172, second lower contact plugs 174, and third lower contact plugs 176, sequentially stacked on the first substrate 101. The lower wiring lines 180 may include a first lower wiring line 182, a second lower wiring line 184, and a third lower wiring line 186. The number of the contact plugs and the wiring lines, forming the lower contact plugs 170 and the lower wiring lines 180, may be varied in example embodiments. The lower contact plugs 170 and the lower wiring lines 180 may include a metal, for example, tungsten (W), copper (Cu), aluminum (Al), and the like.

The memory cell region MCA may include a second substrate 201, gate electrodes 230 spaced apart from each other and stacked perpendicularly to an upper surface of the second substrate 201, interlayer insulating layers 220 alternately stacked with the gate electrodes 230, channels CH disposed to pass through the gate electrodes 230, source conductive layers 210 disposed to pass through the gate electrodes 230, a through wiring region 260 disposed to pass through the gate electrodes 230, a cell region insulating layer 290 on (e.g., covering) the gate electrodes 230, a first upper contact plug 272 and a second upper contact plug 274, as well as upper wiring lines 275. The memory cells may be arranged vertically along respective channels CH to form a single memory cell string.

The second substrate 201 may have an upper surface, extended in an x direction and a y direction. The second substrate 201 may be disposed to have a size equal to that of the first substrate 101, or a size smaller than that of the first substrate 101. The second substrate 201 may include a semiconductor material, for example, a group IV semiconductor. For example, the second substrate 201 may be provided as a polycrystalline silicon layer, but is not limited thereto. The second substrate 201 may be provided as, for example, an epitaxial layer. The second substrate 201 may include at least one well region including impurities. For example, the entirety of the second substrate 201 may form a single p-well region, or the second substrate 201 may include a p-well region and an n-well and/or a p-well formed in the p-well region.

The gate electrodes 230 may be spaced apart from each other and stacked perpendicularly to the second substrate 201 (e.g., in the z direction). As illustrated in FIG. 5, the gate electrodes 230 may be extended in different lengths in an x direction and a y direction. Thus, the second substrate 201 may have a first region I in which the gate electrodes 230 are stacked vertically and a second region II in which a gate electrode 230 in a lower portion among the gate electrodes 230 may be extended further than a gate electrode 230 in an upper portion. The gate electrodes 230 are connected to separate contact plugs to be electrically connected to the upper wiring structure in the second region II.

Respective gate electrodes 230 may form a gate of a ground selection transistor, a plurality of memory cells, and a string selection transistor of the semiconductor device 100. The number of the gate electrodes 230 may be variously changed, depending on the capacity of the semiconductor device 100. The gate electrodes 230 may include a metal material, for example, tungsten (W). According to an example embodiment, the gate electrodes 230 may include a polycrystalline silicon or metal silicide material. In example embodiments, the gate electrodes 230 may further include a diffusion barrier. For example, the diffusion barrier may include tungsten nitride (WN), tantalum nitride (TaN), titanium nitride (TiN), or combinations thereof.

The interlayer insulating layers 220 may be disposed between the gate electrodes 230. The interlayer insulating layers 220 may be spaced apart from each other in a direction perpendicular to an upper surface of the second substrate 201 (e.g., in the z direction) and may be disposed to be extended in an x direction and a y direction, in a manner similar to the gate electrodes 230. The interlayer insulating layers 220 may include an insulating material such as silicon oxide or silicon nitride.

The channels CH may be disposed on the second substrate 201 and spaced apart from each other in rows and columns. The channels CH may be arranged to form a grid pattern on the x-y plane or may be arranged in a zigzag form in one direction. The channels CH may have a columnar shape, and may have a tapered side surface, a width of which becomes narrower toward the second substrate 201 according to an aspect ratio. The channels CH may be disposed in the first region I of the second substrate 201, while dummy channels DCH may be disposed in the second region II. However, at least a portion of the channels CH disposed in the first region I may be a dummy channel. The dummy channels DCH have a structure the same as the channels CH, but may be provided as a pattern without a substantial electrical function in the semiconductor device 100. The dummy channels DCH may be disposed in rows and columns on ends of the gate electrodes 230 in the second region II. However, the arrangement and shape of the channels CH and the dummy channels DCH, illustrated in FIG. 5, are illustrated by way of example, and may be variously modified according to example embodiments.

A channel region 240 may be disposed in the channels CH. In the channels CH, the channel region 240 may be formed in an annular shape, surrounding a channel insulating layer 250, disposed therein. However, according to an example embodiment, the channel region 240 may have a columnar shape such as a circular column or a polygonal column without the channel insulating layer 250. The channel region 240 may be connected to an epitaxial layer 207 in a lower portion thereof. The channel region 240 may include a semiconductor material such as polycrystalline silicon or single crystal silicon. The semiconductor material may be an undoped material, or a material containing p-type or n-type impurities. The channel region 240 may be connected to the second upper contact plugs 274 through a channel pad 255.

In the channels CH, the channel pads 255 may be disposed above the channel region 240. The channel pads 255 may be disposed to be electrically connected to the channel region 240 while being on (e.g., covering) an upper surface of the channel insulating layer 250. The channel pads 255 may include, for example, doped polycrystalline silicon.

A gate dielectric layer 245 may be disposed between the gate electrodes 230 and the channel region 240. The gate dielectric layer 245 may include a tunneling layer, a charge storage layer, and/or a blocking layer, sequentially stacked on the channel region 240. The tunneling layer may allow a charge to tunnel to the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include, for example, silicon oxide (SiO₂), silicon nitride (Si₃N₄), silicon oxynitride (SiON), a high-k dielectric material, or combinations thereof. In example embodiments, at least a portion of the gate dielectric layer 245 may be extended in a horizontal direction along the gate electrodes 230.

The epitaxial layer 207 may be disposed on the second substrate 201 in a lower end of the channels CH, and may be disposed on a side surface of at least one gate electrode 230. A portion of the epitaxial layer 207 may be disposed in a recessed area of the second substrate 201. A level of an upper surface of the epitaxial layer 207 may be higher than that of an upper surface of a lowermost gate electrode 230 and may be lower than a lower surface of a gate electrode 230, directly above the lowermost gate electrode 230, but is not limited to that illustrated therein. In example embodiments, the epitaxial layer 207 may be omitted. In this case, the channel region 240 may be directly connected to the second substrate 201.

The source conductive layers 210 may be disposed in the first region I and the second region II and extended in an x direction. The source conductive layers 210 may pass through the gate electrodes 230 between the channels CH to be connected to the second substrate 201, and may be spaced apart from the gate electrodes 230 to be electrically insulated by a source insulating layer 215. Thus, the gate electrodes 230 may be spaced apart from each other at predetermined intervals in a y direction with the source conductive layer 210 interposed therebetween. The source conductive layer 210 may form the common source line CSL described previously with reference to FIG. 2. The source conductive layer 210 may be arranged at predetermined intervals in a y direction, for example, one every four to five rows of the channels CH, but the inventive concepts are not limited thereto. The source conductive layer 210 may have a shape having a width that is reduced toward the second substrate 201 due to a high aspect ratio, but is not limited thereto. In some embodiments, the source conductive layer 210 may have a side surface that is perpendicular to an upper surface of the second substrate 201. In example embodiments, an impurity region may be disposed in the second substrate 201 to be in contact with the source conductive layer 210.

The through wiring region 260 may be disposed to pass through the gate electrodes 230 and the interlayer insulating layers 220 from an upper portion of the gate electrodes 230. The through wiring region 260 may be a region including a wiring structure for connection of the memory cell region MCA and the peripheral circuit region PC. The through wiring region 260 may be a region including the connecting metal layer CML of FIG. 3. The through wiring region 260 may be at least one region between the channels CFI in the first region I, in which the channels CH are disposed. As illustrated in FIG. 5, the through wiring region 260 may be provided as a plurality of through wiring regions disposed at predetermined intervals between the channels CH in the memory cell region MCA. The through wiring region 260 may have a shape in which a lower (e.g., closer to the second substrate 201) surface is narrower than an upper surface according to an aspect ratio. However, the number, size, arrangement, and shape of the through wiring region 260 may be variously changed according to example embodiments.

In detail, the through wiring region 260 may include a conductive region 263 passing through the gate electrodes 230 and connected to the second substrate 201, and through contact plugs 265 passing through the conductive region 263 and the second substrate 201 and extended to a portion of an upper portion of the peripheral region insulating layer 190. In some embodiments, the through contact plugs 265 may be connected to the lower wiring lines 180 of the peripheral circuit region PC. The through wiring region 260 may further include a side insulating layer 262 disposed between the conductive region 263 and the gate electrodes 230, and a wiring insulation layer 264 disposed between the through contact plugs 265 and the conductive region 263.

The conductive region 263 may be disposed to be on (e.g., surround) portions of the through contact plugs 265 and the wiring insulation layer 264. The conductive region 263 may be formed of a conductive material, and may be physically and electrically connected to the second substrate 201. Thus, the conductive region 263 may receive an electrical signal through the first upper contact plug 272 connected thereabove, and may then transmit the electrical signal to the second substrate 201. The conductive region 263 may receive a voltage, for example, a voltage applied to a well region in the second substrate 201. For example, during an erasing operation of the memory cells of the semiconductor device 100, an erasing voltage may be applied to the second substrate 201 through the conductive region 263. As the through wiring region 260 passes through the gate electrodes 230 and may be disposed in the memory cell region MCA, when an erasing voltage is applied to the second substrate 201 through the conductive region 263, the uniformity of the erasing speed between the memory cell strings may be improved. In other words, when an erasing voltage is applied from an external source to the memory cell region MCA, a difference in the erasing speed may occur depending on the arrangement position of the channels CH. However, when an erasing voltage is applied through the conductive region 263, the deviation caused by the position of the channels CH may be reduced.

The conductive region 263 may be formed of, for example, a material the same as the second substrate 201, and may be formed of a material different from the through contact plugs 265. For example, the conductive region 263 may be formed of polycrystalline silicon. According to example embodiments, the conductive region 263 may be recessed in the second substrate 201 to a predetermined depth.

The through contact plugs 265 may be extended perpendicularly to the first substrate 101 and the second substrate 201, and electrically connect the memory cell region MCA to the circuit devices 120 of the peripheral circuit region PC. For example, the through contact plugs 265 may allow the bit line BL of the memory cell region MCA (see FIG. 1) to be electrically connected to the circuit device 120 of the peripheral circuit region PC. However, a wiring structure, electrically connecting the memory cell region MCA to the circuit devices 120 of the peripheral circuit region PC, is not limited to the through contact plugs 265. For example, an additional wiring structure may be further disposed in an external region of the second region II. The through contact plugs 265 may be connected to the upper wiring lines 275 in an upper portion thereof, but may be connected to a separate contact plug according to example embodiments. The through contact plugs 265 may include a metal, for example, tungsten (W), copper (Cu), aluminum (Al), and the like.

The number and shape of the through contact plugs 265, passing through a single conductive region 263, may be variously changed according to example embodiments. According to example embodiments, the through contact plugs 265 may have a shape in which a plurality of layers are connected. Moreover, according to example embodiments, wiring structures in the form of a wiring line may be further disposed in the conductive region 263 in addition to the through contact plugs 265.

The side insulating layer 262 and the wiring insulation layer 264 may be disposed to be on (e.g., surround) portions of the conductive region 263 and the through contact plugs 265, respectively. The side insulating layer 262 may electrically isolate the conductive region 263 from the gate electrodes 230, while the wiring insulation layer 264 may electrically isolate the through contact plugs 265 from the conductive region 263. The side insulating layer 262 may be disposed on the second substrate 201, while the wiring insulation layer 264 may be extended into the second substrate 201. According to example embodiments, the wiring insulation layer 264 may be extended into the peripheral region insulating layer 190. The side insulating layer 262 and the wiring insulation layer 264 may be formed of an insulating material, for example, silicon oxide and/or silicon nitride.

The cell region insulating layer 290 may be disposed to be on (e.g., to cover) the second substrate 201, as well as the gate electrodes 230 and the peripheral region insulating layer 190 on the second substrate 201. The cell region insulating layer 290 may be formed of an insulating material.

The first upper contact plug 272 and the second upper contact plug 274 as well as the upper wiring lines 275 may form an upper wiring structure electrically connected to memory cells in the memory cell region MCA. The first upper contact plug 272 and the second upper contact plug 274 as well as the upper wiring lines 275 may be electrically connected to the channels CH and/or the through contact plugs 265. Moreover, in a region which is not shown, the upper wiring structure may also be electrically connected to the source conductive layer 210. The number of contact plugs and wiring lines, forming the upper wiring structure, may be varied in example embodiments. The first upper contact plug 272 and the second upper contact plug 274 as well as the upper wiring lines 275 may include a metal, for example, tungsten (W), copper (Cu), aluminum (Al), and the like. In some embodiments, the first upper contact plug 272 and the second upper contact plug 274 may be at a same level. In some embodiments, the first upper contact plug 272 and the second upper contact plug 274 may have upper surfaces that are coplanar.

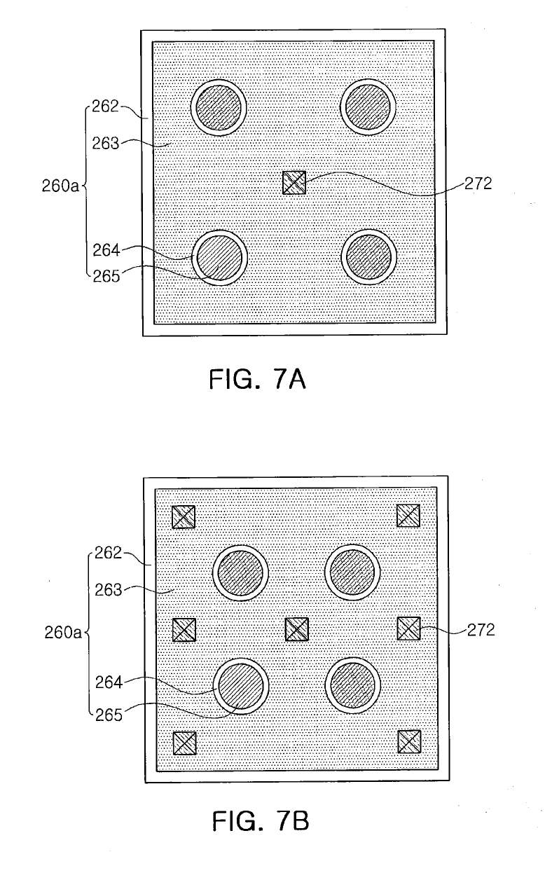

FIGS. 7A and 7B are schematic plan views of a semiconductor device according to example embodiments of the inventive concepts. FIGS. 7A and 7B illustrate layouts of a region corresponding to the through wiring region 260 in FIG. 5.

Referring to FIGS. 7A and 7B, a through wiring region 260a may include through contact plugs 265 arranged in rows and columns, a wiring insulation layer 264 on (e.g., surrounding) the through contact plugs 265, a conductive region 263 on (e.g., surrounding) the through contact plugs 265 and the wiring insulation layer 264, and a side insulating layer 262 on (e.g., surrounding) the conductive region 263. The through contact plugs 265 may be provided as a plurality of through contact plugs arranged according to a size of the through wiring region 260a.

The first upper contact plugs 272 may be disposed on the conductive region 263. As illustrated in FIG. 7A, the first upper contact plugs 272 may be provided as a single first upper contact plug on the conductive region 263. In some embodiments, as illustrated in FIG. 7B, the first upper contact plugs 272 may be provided as plurality of first upper contact plugs arranged to be spaced apart from each other on the conductive region 263. The number of the first upper contact plugs 272 connected to a single conductive region 263 may be determined in consideration of a size of the first upper contact plugs 272, a size of an electrical signal applied through the first upper contact plugs 272, a size of the conductive region 263, and the like. In some embodiments, as discussed further herein, in a portion of the through wiring regions 260a, the conductive region 263 may not be connected to the first upper contact plugs 272. The arrangement of the first upper contact plugs 272 described above may be determined in consideration of a unit in which an electrical signal is applied to the second substrate 201 (see FIG. 6), an arrangement unit of the through wiring regions 260a, and the like.

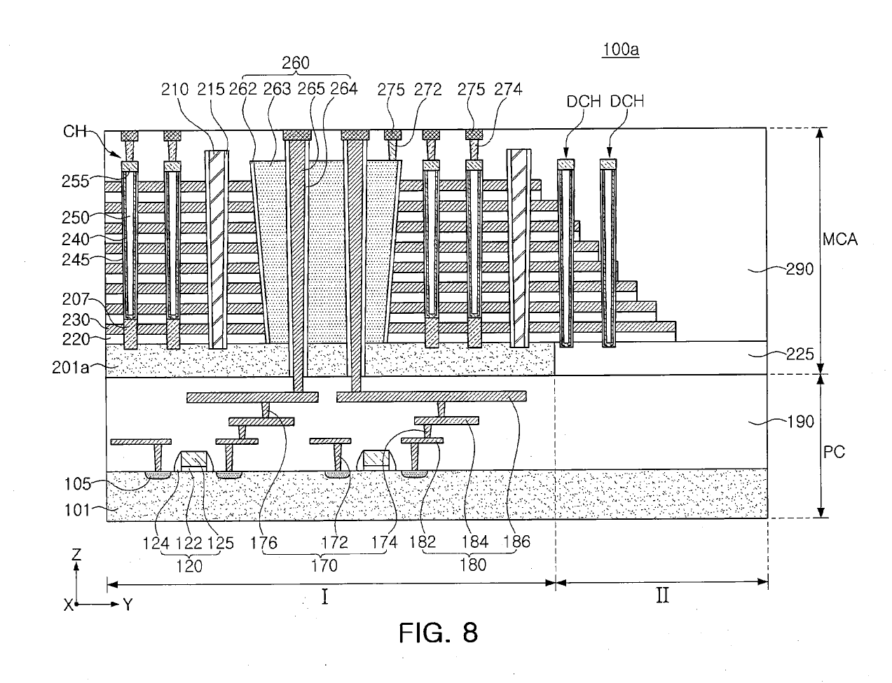

FIG. 8 is a schematic cross-sectional view of a semiconductor device according to example embodiments of the inventive concepts.

Referring to FIG. 8, in a semiconductor device 100a, in a manner different from the example embodiment of FIG. 6, a second substrate 201a may not be extended into the second region II, but may be limited to the first region I.

In the semiconductor device 100a, an electrical signal applied to the second substrate 201a may be applied through the conductive region 263 of the through wiring region 260. Thus, it is not necessary to provide a separate region for wiring with the second substrate 201a outside the second region II, so the semiconductor device 100a may have a structure in which the second substrate 201a is not extended into the second region II. The second substrate 201a may be limited to a region in which the channels CH are disposed for electrical connection with the channels CH.

Dummy channels DCH may be disposed in the second region II of the semiconductor device 100a. In this case, in the second region II, a second substrate 201a may not be disposed below the dummy channels DCH, so an epitaxial layer 207 may not be formed below the dummy channels DCH. Thus, as illustrated in FIG. 8, in the second region II, a configuration of the dummy channels DCH may be different from the channels CH. The dummy channels DCH may be connected to a substrate insulating layer 225, disposed at a level substantially equal to that of the second substrate 201a, in a lower end thereof. The substrate insulating layer 225 may be formed of an insulating material, and may be formed of a portion of the cell region insulating layer 290 or the interlayer insulating layer 220, but is not limited thereto. In the example embodiment, the dummy channels DCH are formed not on the second substrate 201a, but on the substrate insulating layer 225, and may not include the epitaxial layer 207, thus, the dummy channels may prevent a leakage current from occurring due to a defect of the dummy channels DCH.

According to example embodiments, a lower end of the dummy channels DCH in the second region II may be located at a level lower than that of a lower end of the channels CH in the first region I. As degrees of etching of the second substrate 201a and the substrate insulating layer 225 may be different, the level difference described above may occur. When a size of the dummy channels DCH in the second region II is different from a size of the channels CH in the first region I, the level difference described above may occur.

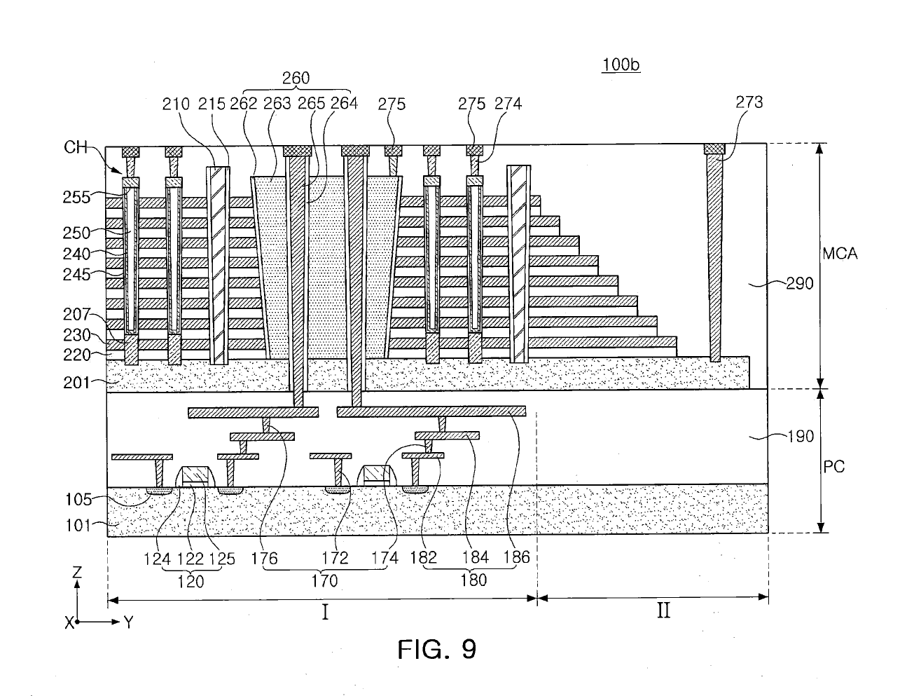

FIG. 9 is a schematic cross-sectional view of a semiconductor device according to example embodiments of the inventive concepts.

Referring to FIG. 9, in a semiconductor device 100b, in a manner different from the example embodiment of FIG. 6, a first upper contact plug 272 may not be disposed on a conductive region 263, and a substrate contact plug 273 may be further disposed outside of gate electrodes 230.

The substrate contact plug 273 may be a wiring structure for applying an electrical signal to the second substrate 201. The substrate contact plug 273 may pass through the cell region insulating layer 290 and may be connected to the second substrate 201. The substrate contact plug 273 may be formed of a conductive material, and may be formed, for example, of a material that is substantially the same as that of the through contact plug 265.

However, the inventive concepts are not limited to a configuration in which one of the first upper contact plug 272 and the substrate contact plug 273 is alternatively disposed. Thus, according to example embodiments, in a manner similar to the example embodiment of FIG. 6, while a first upper contact plug 272 may be disposed on the conductive region 263, a substrate contact plug 273 may be additionally disposed on the second substrate 201. Moreover, in a region of the semiconductor device 100b, the first upper contact plug 272 and the substrate contact plug 273 may be disposed together, and in other regions of the semiconductor device 100b, only one of the first upper contact plug 272 of the substrate contact plug 273 may be disposed.

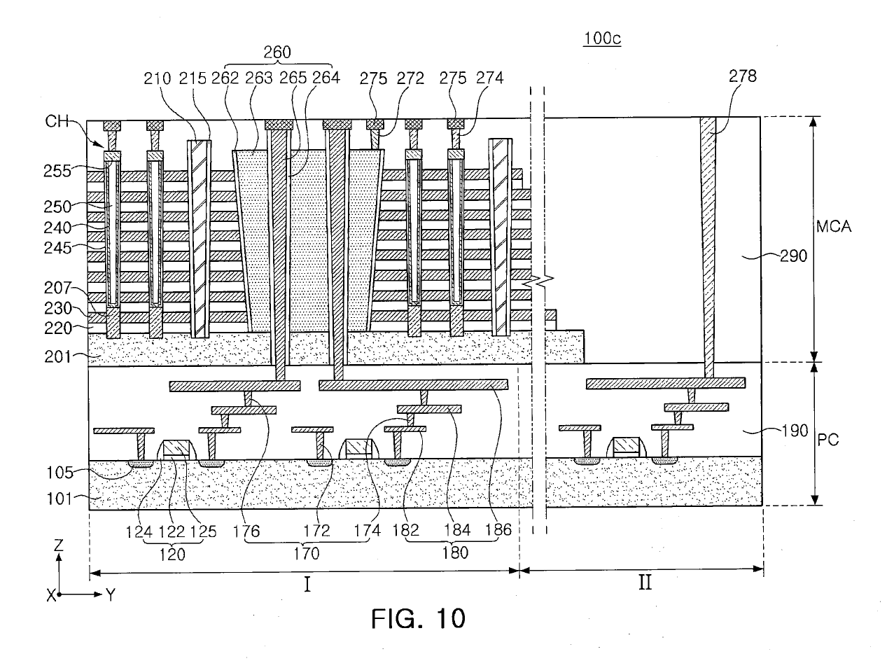

FIG. 10 is a schematic cross-sectional view of a semiconductor device according to example embodiments of the inventive concepts.

Referring to FIG. 10, a semiconductor device 100c may further include an outer through contact plug 278, which is a through wiring structure disposed outside of the gate electrodes 230, in addition to the through contact plug 265 passing through the gate electrodes 230.

The outer through contact plug 278 may pass through the cell region insulating layer 290 and a portion of the peripheral region insulating layer 190 and may be connected to the lower wiring lines 180, outside the second substrate 201. The outer through contact plug 278 may be formed of a conductive material. The outer through contact plug 278 may be a wiring structure connected to a circuit device 120, constituting peripheral circuits which may, in some embodiments, be different from those to which the through contact plug 265 is connected. The arrangement of the outer through contact plug 278 may be applied to other example embodiments described previously with reference to FIGS. 6, 8, and 9.

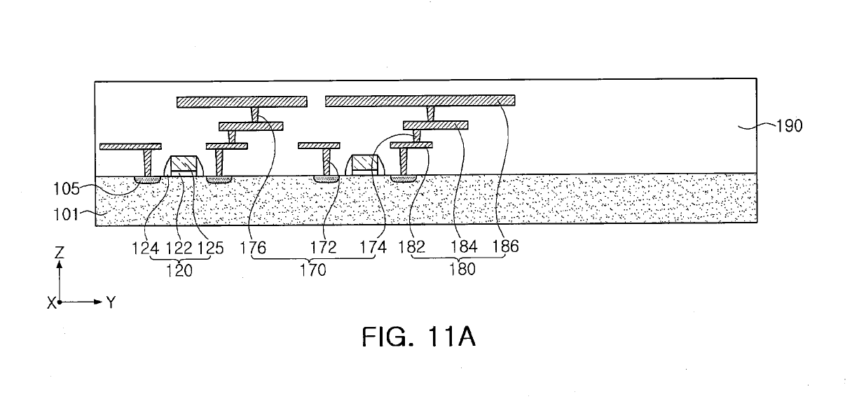

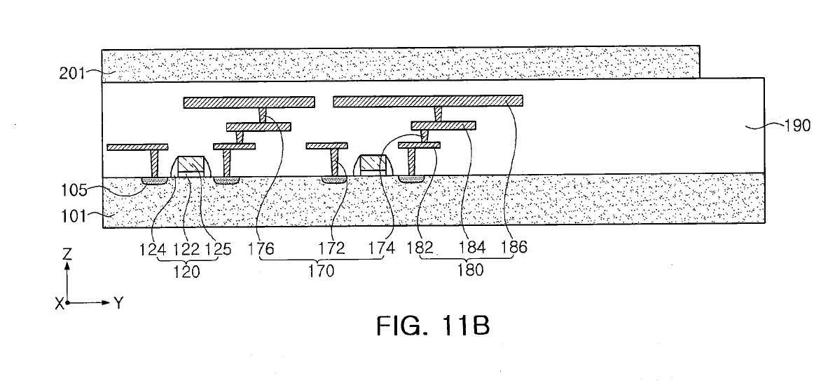

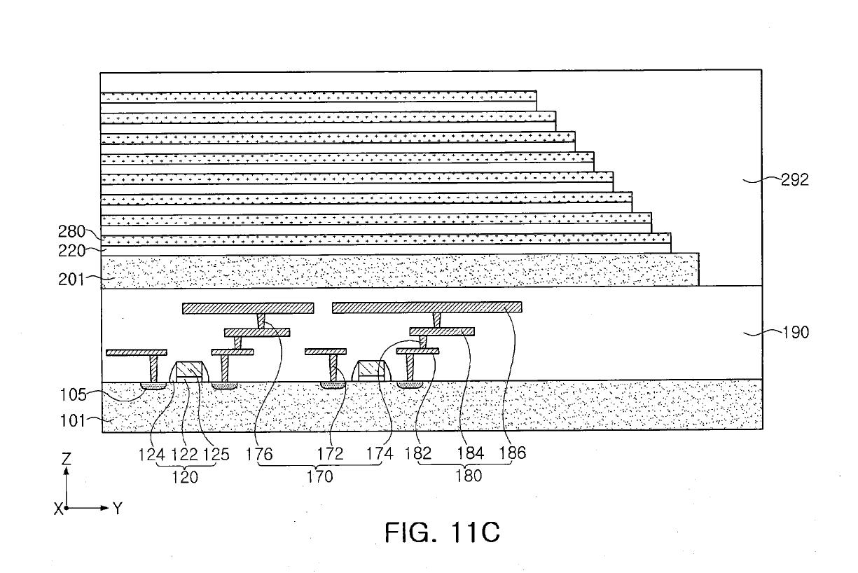

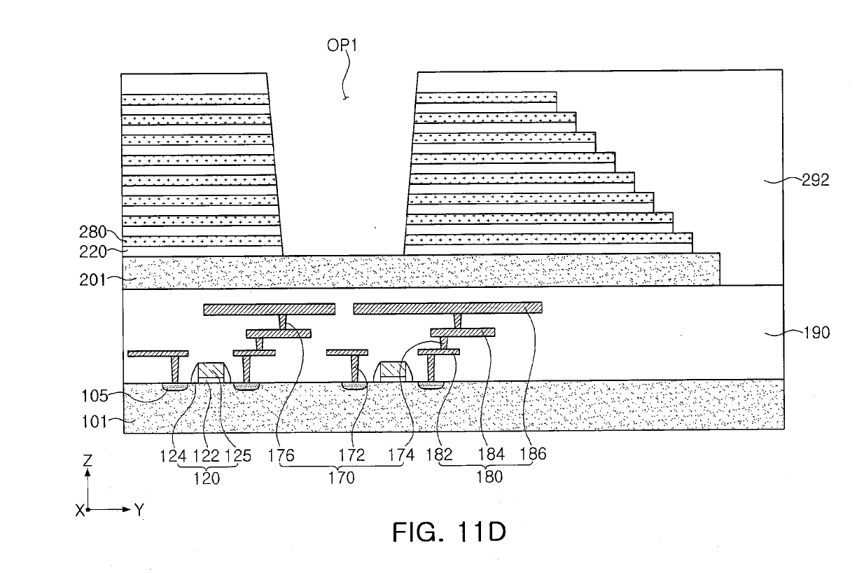

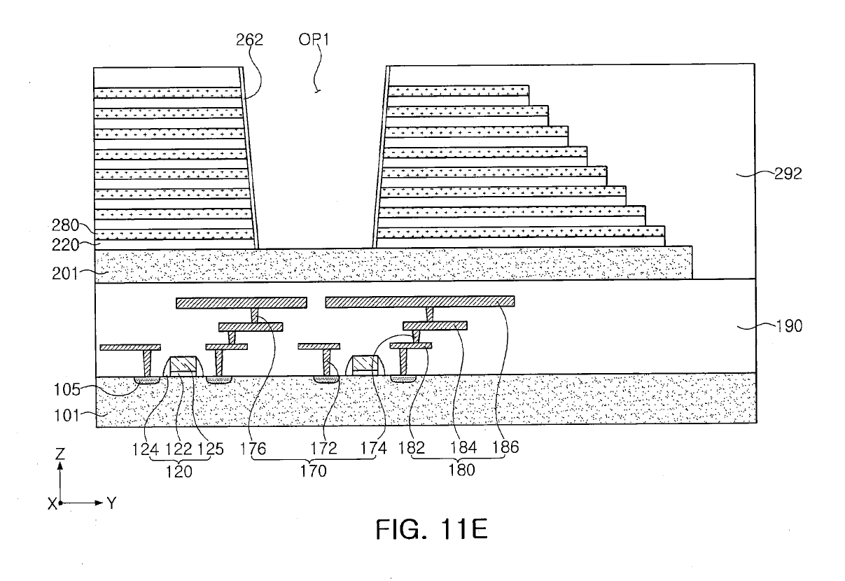

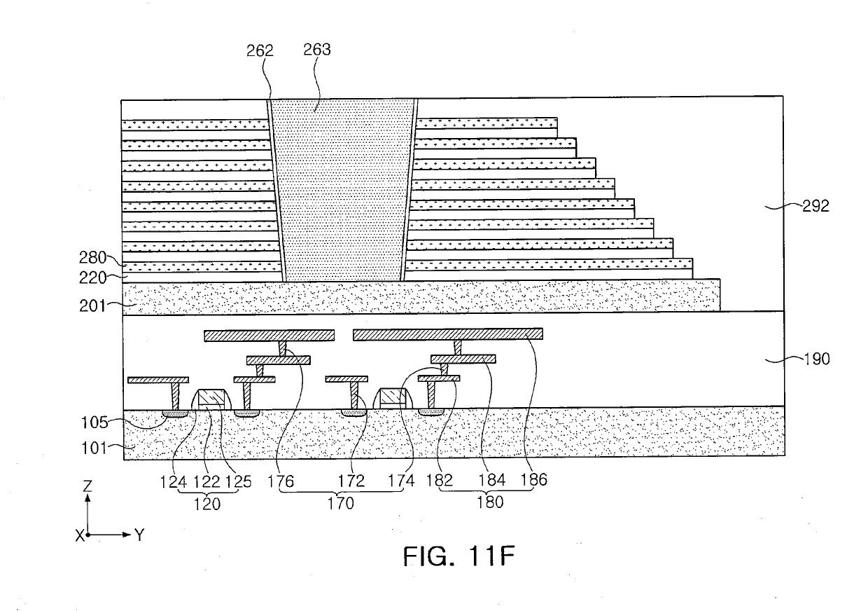

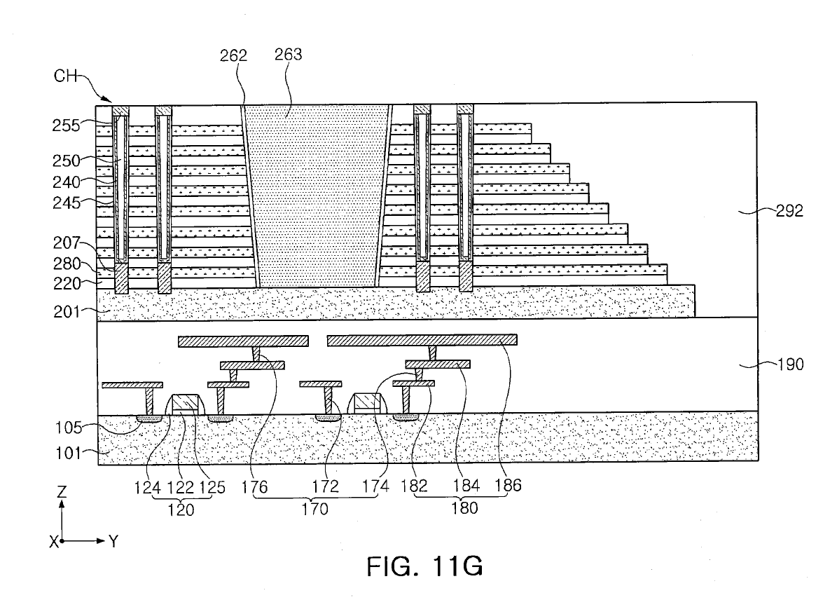

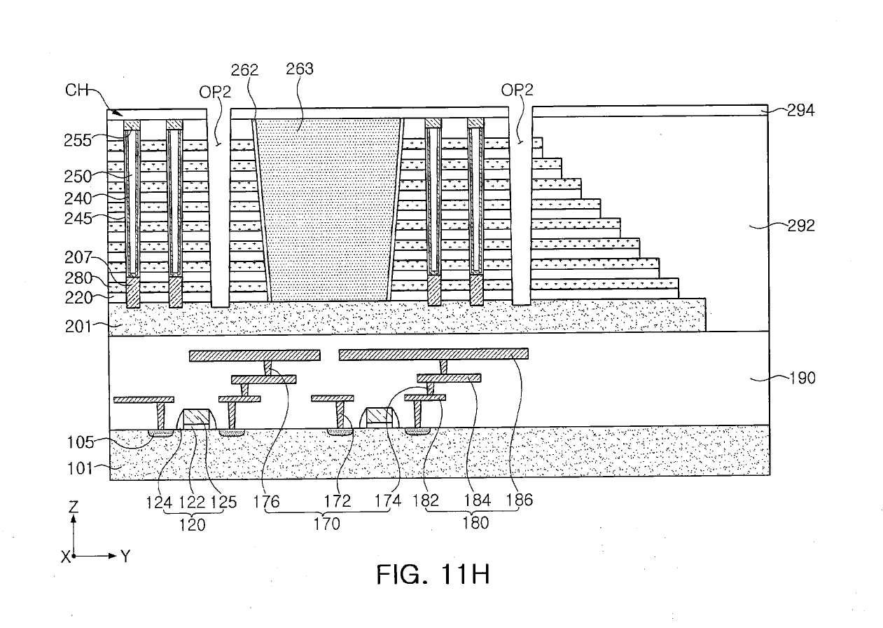

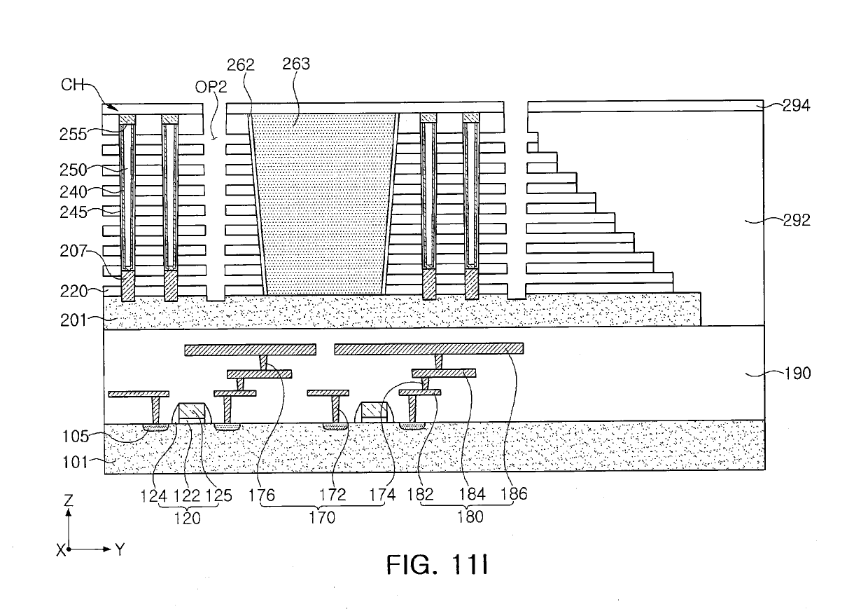

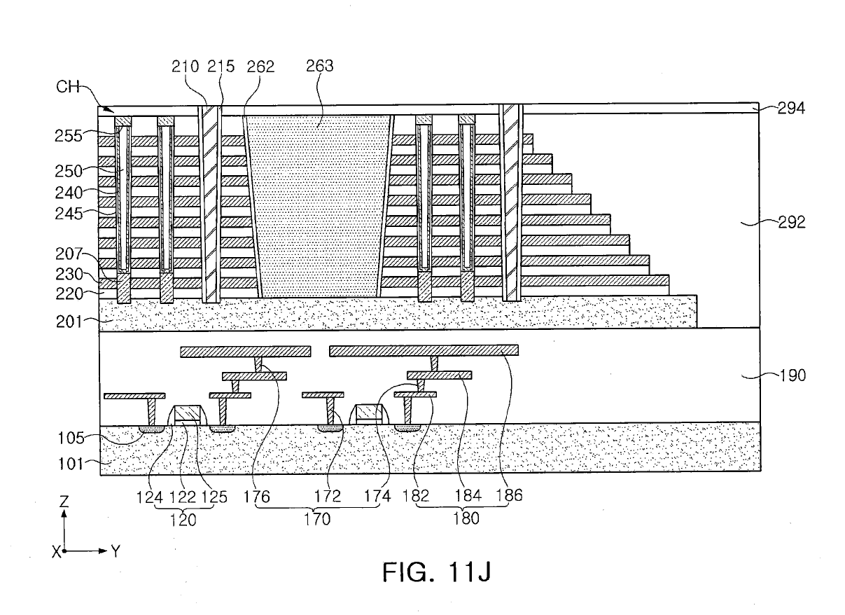

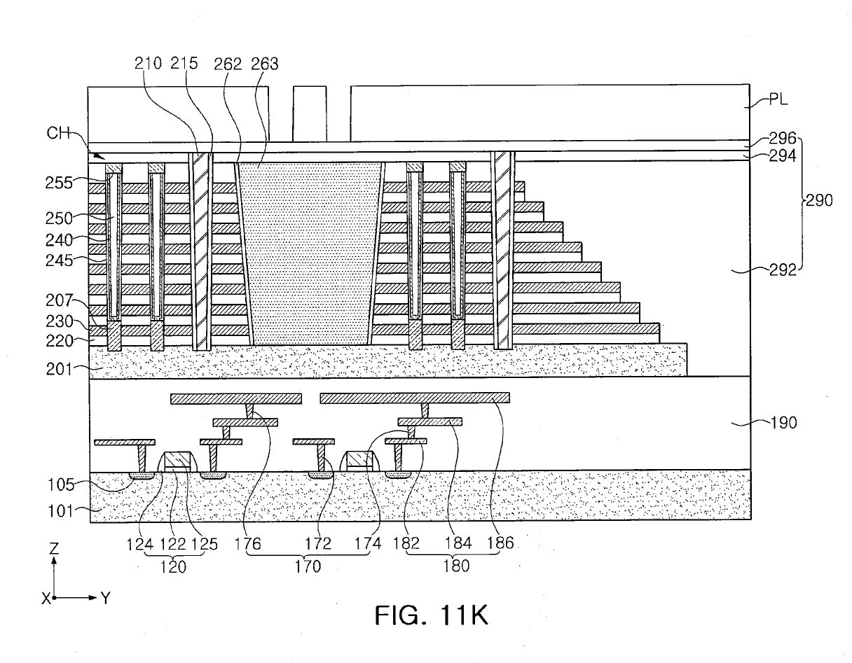

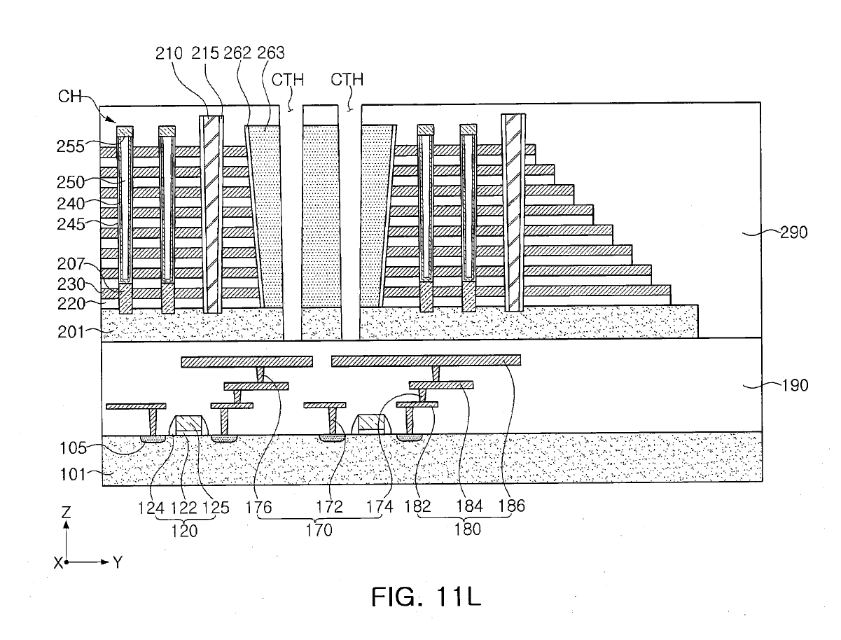

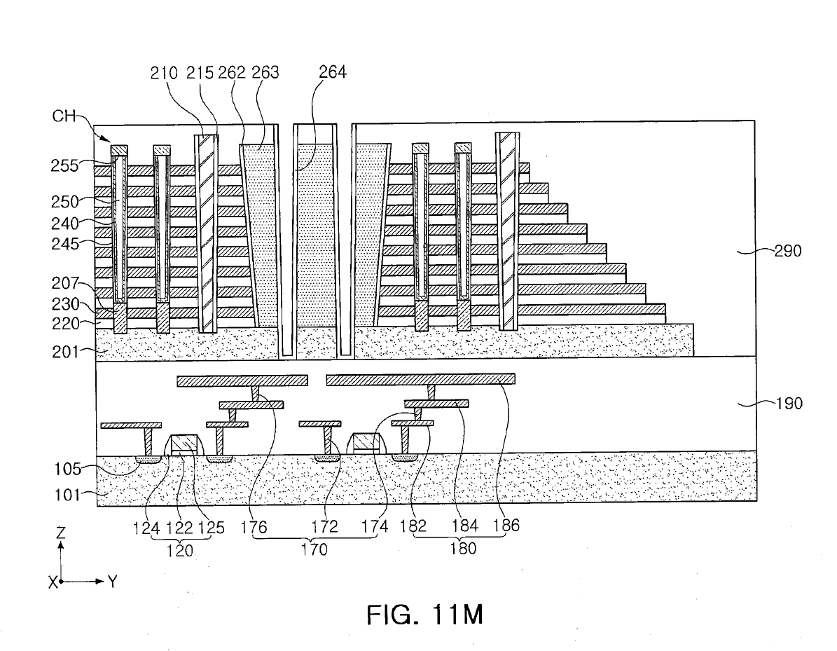

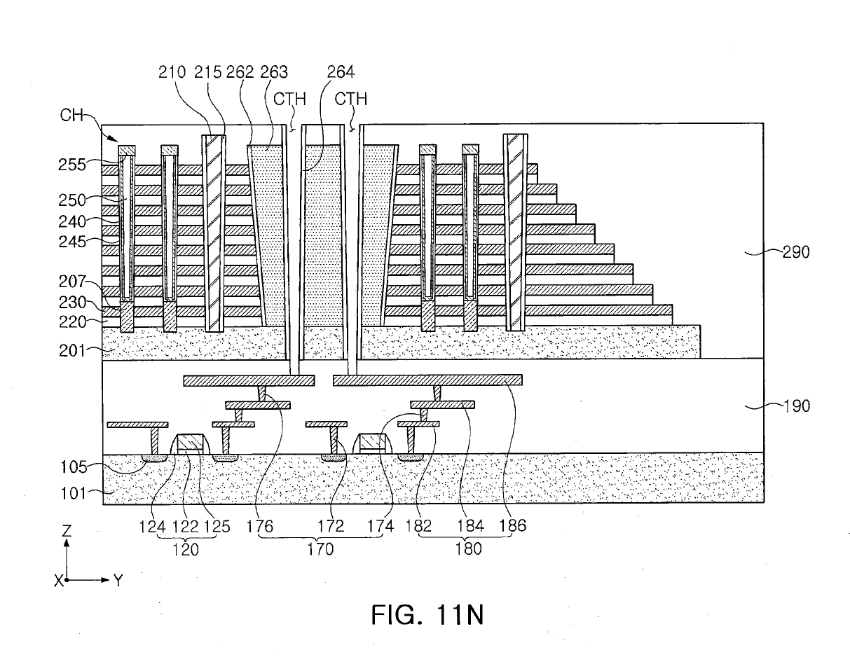

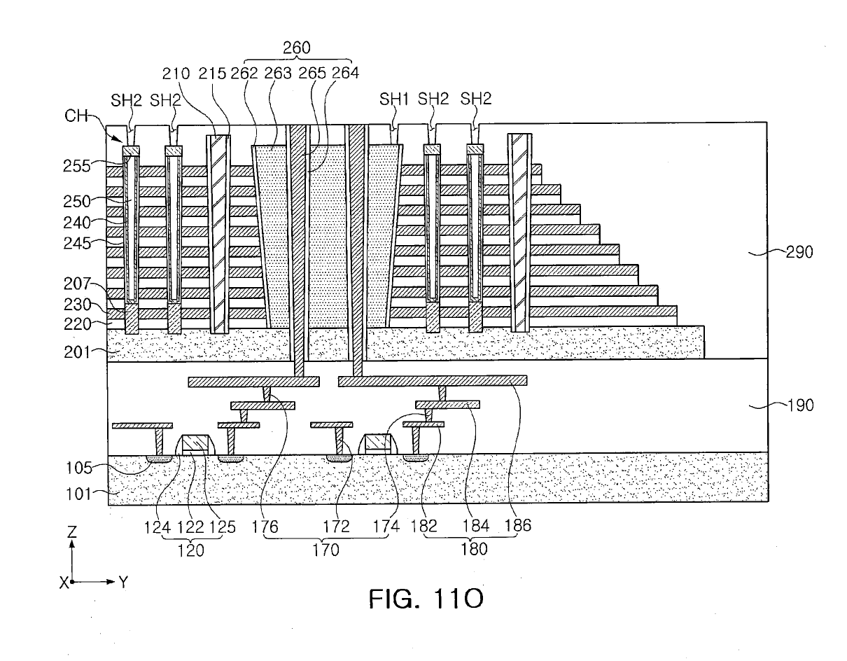

FIGS. 11A to 11O are schematic cross-sectional views illustrating a method for manufacturing a semiconductor device according to example embodiments of the inventive concepts. In FIGS. 11A to 11O, regions corresponding to a region illustrated in FIG. 6 are illustrated.

Referring to FIG. 11A, circuit devices 120 and lower wiring structures may be formed on a first substrate 101.

First, the circuit gate dielectric layer 122 and the circuit gate electrode layer 125 may be sequentially formed on the first substrate 101. The circuit gate dielectric layer 122 and the circuit gate electrode layer 125 may be formed using Atomic Layer Deposition (ALD) or Chemical Vapor Deposition (CVD). The circuit gate dielectric layer 122 may be formed of silicon oxide, and the circuit gate electrode layer 125 may be formed of at least one of polycrystalline silicon or a metal silicide layer, but is not limited thereto. Next, a spacer layer 124 and impurity regions 105 may be formed on both sidewalls of the circuit gate dielectric layer 122 and the circuit gate electrode layer 125. According to example embodiments, the spacer layer 124 may be provided as a plurality of layers. Next, impurity regions 105 may be formed by performing ion implantation.

After a portion of the peripheral region insulating layer 190 is formed, a portion thereof is etched and removed, and a conductive material is filled therein. Thus, lower contact plugs 170, of the lower wiring structures, may be provided. After a conductive material is deposited, the conductive material is patterned. Thus, the lower wiring lines 180 may be provided.

The peripheral region insulating layer 190 may be provided as a plurality of insulating layers. A portion of the peripheral region insulating layer 190 may be formed in respective steps for forming the lower wiring structures, and a portion thereof may be formed above the third lower wiring line 186. As a result, the peripheral region insulating layer 190 may be formed to be on (e.g., to cover) the circuit devices 120 and the lower wiring structures.

Referring to FIG. 11B, a second substrate 201 may be formed above the peripheral region insulating layer 190.

The second substrate 201 may be formed on the peripheral region insulating layer 190. The second substrate 201 may be formed of, for example, polycrystalline silicon, and may be formed using a CVD process. The polycrystalline silicon, forming the second substrate 201, may include impurities. The second substrate 201 may be formed to be smaller than the first substrate 101, but is not limited thereto.

Referring to FIG. 11C, the sacrificial layers 280 and the interlayer insulating layers 220 may be alternately stacked on the second substrate 201, and portions of the sacrificial layers 280 and the interlayer insulating layers 220 may be removed to allow the sacrificial layers 280 to be extended in different lengths in an edge region.

The sacrificial layers 280 may be a layer which is to be replaced with the gate electrodes 230 in a subsequent process. The sacrificial layers 280 may be formed of a material which is to be etched while having etch selectivity with respect to the interlayer insulating layers 220. For example, the interlayer insulating layer 220 may be formed of at least one of silicon oxide and silicon nitride, while the sacrificial layers 280 may be formed of a material, which is different from the interlayer insulating layer 220 and which is selected from the group consisting of silicon, silicon oxide, silicon carbide, and silicon nitride. In example embodiments, thicknesses of the interlayer insulating layers 220 may not be all equal.

Next, a photolithography process and an etching process with respect to the sacrificial layers 280 may be performed so that sacrificial layers 280 in an upper portion are extended to be shorter than sacrificial layers 280 in a lower portion. Thus, the sacrificial layers 280 may be stepped. In example embodiments, the sacrificial layers 280 may be formed to have a relatively great thickness in an end thereof, a process therefor may be further performed. Next, a first cell region insulating layer 292, covering an upper portion of a stacked structure of the sacrificial layers 280 and the interlayer insulating layers 220, may be provided.

Referring to FIG. 11D, a first opening OP1, passing through the stacked structure of the sacrificial layers 280 and the interlayer insulating layers 220, may be provided.

The first opening OP1 may be formed in a region in which the through wiring region 260 (see FIG. 1) is to be disposed. After a separate mask pattern such as a photoresist layer is provided, portions of the sacrificial layers 280 and the interlayer insulating layers 220 may be removed using the separate mask pattern, and thus a first opening OP1 may be provided. According to example embodiments, when the first opening OP1 is formed, a portion of a second substrate 201 may be recessed.

Referring to FIG. 11E, a side insulating layer 262 covering side surfaces of the sacrificial layers 280 and the interlayer insulating layers 220 exposed through the first opening OP1 may be provided.

After an insulating material is deposited, an etch-back process is performed, so the insulating material is removed from an upper surface of the second substrate 201. Thus, the side insulating layer 262 may be provided. The side insulating layer 262 may be provided on an inner sidewall of the first opening OP1 while having the form of a spacer.

Referring to FIG. 11F, the first opening OP1 may be filled to provide a conductive region 263.

After a conductive material is entirely deposited, planarizing may be performed, for example, by using a chemical mechanical polishing (CMP) process. Thus, the conductive region 263 may be provided. The conductive region 263 may be formed of, for example, polycrystalline silicon, and may be provided using a CVD or physical vapor deposition (PVD) process. The conductive region 263 may be formed of a material different from the first cell region insulating layer 292, so the planarizing process may be stopped in the first cell region insulating layer 292 without a separate etch stop layer.

Referring to FIG. 11G, the channels CH, passing through the stacked structure of the sacrificial layers 280 and the interlayer insulating layers 220, may be provided.

First, the stacked structure may be anisotropically etched to form channel holes. Due to the height of the stacked structure, a sidewall of the channel holes may not be perpendicular to an upper surface of the second substrate 201. In example embodiments, the channel holes may be formed to recess a portion of the second substrate 201.

Next, in the channel holes, the epitaxial layer 207, the channel region 240, the gate dielectric layer 245, the channel insulating layer 250, and the channel pads 255 may be formed to form the channels CH. The epitaxial layer 207 may be formed using a selective epitaxial growth (SEG) process. The epitaxial layer 207 may be provided as a single layer or a plurality of layers. The epitaxial layer 207 may include polycrystalline silicon, single crystalline silicon, polycrystalline germanium, and/or single crystalline germanium, which may or may not be doped with impurities. The gate dielectric layer 245 may be formed to have a uniform thickness using, for example, an ALD or CVD process. In the operation described above, at least a portion of the gate dielectric layer 245, vertically extended along the channel region 240, may be provided. The channel region 240 may be formed on the gate dielectric layer 245 in the channels CH. The channel insulating layer 250 may be formed to fill the channels CH, and may be provided as an insulating material. However, according to example embodiments, a gap between the channel regions 240 may be filled with the conductive material other than the channel insulating layer 250. The channel pads 255 may be formed of a conductive material, for example, polycrystalline silicon.

Referring to FIG. 11H, second openings OP2, passing through the stacked structure of the sacrificial layers 280 and the interlayer insulating layers 220, may be provided.

Before the second openings OP2 are provided, the second cell region insulating layer 294, covering an upper surface of the channels CH, may be further provided. The second openings OP2 may be provided in a region in which the source conductive layer 210 (see FIG. 6) is to be disposed. The second openings OP2 may be provided to expose the second substrate 201 by anisotropically etching the stacked structure. The second openings OP2 may be provided in the form of a trench extended in an x direction.

Referring to FIG. 11I, sacrificial layers 280, exposed through the second openings OP2, may be removed.

The sacrificial layers 280 may be selectively removed with respect to the interlayer insulating layers 220, for example, using wet etching. Thus, side walls of the channels CH and the side insulating layer 262 may be partially exposed between the interlayer insulating layers 220.

Referring to FIG. 11J, the gate electrodes 230 may be formed in a region from which the sacrificial layers 280 are removed, and the source insulating layers 215 and the source conductive layer 210 may be formed in the second openings OP2.

A conductive material may be filled in a region from which the sacrificial layers 280 are removed, and thus the gate electrodes 230 may be provided. The gate electrodes 230 may include, for example, a metal, polycrystalline silicon, and/or a metal silicide material. In example embodiments, when the gate dielectric layer 245 has a region extended in parallel to the second substrate 201 along the gate electrodes 230, the region may be formed first before the gate electrodes 230 are provided.

To form the source insulating layers 215, an insulating material may be formed and removed from the second substrate 201 to allow an upper surface of the second substrate 201 to be exposed. Thus, the source insulating layers 215 may be manufactured in the form of a spacer. A conductive material for forming the source conductive layer 210 may be deposited between the source insulating layers 215. Thus, the source conductive layer 210 may be provided. The gate electrodes 230 may be spaced apart from each other at predetermined intervals in a y direction by the source insulating layers 215 and the source conductive layer 210.

Referring to FIG. 11K, the third cell region insulating layer 296 may be formed on the second cell region insulating layer 294, while a mask layer PL may be formed on the third cell region insulating layer 296.

The third cell region insulating layer 296 may be formed to be on (e.g., to cover) an upper surface of the source conductive layer 210, but may be omitted according to example embodiments. The cell region insulating layer 290 may be a layer formed of the first cell region insulating layer 292, the second cell region insulating layer 294, and the third cell region insulating layer 296. However, when a material forming respective layers is the same, a boundary between layers may not be recognized.

A mask layer PL may be a layer patterned for formation of the through contact plugs 265 (see FIG. 6). The mask layer PL may include a photoresist layer, and may further include a hard mask layer in a lower portion thereof.

Referring to FIG. 11L, the mask layer PL may be used to form through contact holes CTH.

The through contact holes CTH may be formed to pass through a cell region insulating layer 290 on the conductive region 263, the conductive region 263, and the second substrate 201. The through contact holes CTH may be formed using an etching process. The etching process may be performed first, for example, with respect to the cell region insulating layer 290, and may be performed under different process conditions with respect to the conductive region 263 and/or the second substrate 201.

When the conductive region 263 is formed of, for example, polycrystalline silicon, as compared to the case in which the conductive region 263 is formed of an insulating material, the through contact holes CTH may have an improved profile. In this case, because an etching process with respect to silicon is relatively easily performed, the through contact holes CTH may have an improved profile. In detail, even when the number of the gate electrodes 230 having been stacked is large, a difference in a diameter of an upper portion and a lower portion of the through contact holes CTH may be relatively small, and the through contact holes CTH may be extended downwardly without occurrence of bending. Moreover, the through contact holes CTH may maintain a circular shape of a cross section on a plane.

Referring to FIG. 11M, a wiring insulation layer 264 covering an inner side surface and a lower surface of the through contact holes CTH may be provided.

An insulating material may be deposited in a uniform thickness in the through contact holes CTH, so the wiring insulation layer 264 may be provided. The wiring insulation layer 264 may be provided on the conductive region 263 and the inner side surface of the second substrate 201, exposed through the through contact holes CTH.

Referring to FIG. 11N, the through contact holes CTH may be extended downwardly to expose the third lower wiring line 186.

First, from a lower end of the through contact holes CTH, the wiring insulation layer 264 on the peripheral region insulating layer 190 may be removed. Next, a peripheral region insulating layer 190 below the through contact holes CTH may be removed, so the through contact holes CTH may be extended to expose the third lower wiring line 186 of the peripheral circuit region PC.

Referring to FIG. 11O, a conductive material may filled in the through contact holes CTH to form the through contact plugs 265, and the first upper contact hole SH1 and the second upper contact hole SH2 may be provided.

A conductive material may be deposited in the through contact holes CTH. Thus, the through contact plugs 265 may be provided. Thus, as a result, the through wiring region 260, including the conductive region 263, the through contact plugs 265, the side insulating layer 262, and the wiring insulation layer 264, may be provided. The through contact plugs 265 may be formed of, for example, tungsten (W), and may include a diffusion barrier, deposited first. For example, the diffusion barrier may include tungsten nitride (WN), tantalum nitride (TaN), titanium nitride (TiN), or combinations thereof.

The cell region insulating layer 290 may be removed to expose upper surfaces of the channels CH and the conductive region 263. Thus, the first upper contact hole SH1 and the second upper contact hole SH2 may be provided.

Next, referring to FIG. 6, the first upper contact hole SH1 and the second upper contact hole SH2 may be filled with a conductive material, so the first upper contact plug 272 and the second upper contact plug 274 may be provided. Next, the upper wiring lines 275, connected to the first upper contact plug 272, the second upper contact plug 274, and the through contact plugs 265, may be provided.

As set forth above, according to example embodiments of the present inventive concepts, a through wiring region including a conductive region in a memory cell region is disposed, so a semiconductor device having improved reliability may be provided.

It will be understood that although the terms “first,” “second,” etc. are used herein to describe members, regions, layers, portions, sections, components, and/or elements in example embodiments of the inventive concepts, the members, regions, layers, portions, sections, components, and/or elements should not be limited by these terms. These terms are only used to distinguish one member, region, portion, section, component, or element from another member, region, portion, section, component, or element. Thus, a first member, region, portion, section, component, or element described below may also be referred to as a second member, region, portion, section, component, or element without departing from the scope of the inventive concepts. For example, a first element may also be referred to as a second element, and similarly, a second element may also be referred to as a first element, without departing from the scope of the inventive concepts.

Spatially relative terms, such as “beneath,” “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by those of ordinary skill in the art to which the inventive concepts pertain. It will also be understood that terms, such as those defined in commonly used dictionaries, should be interpreted as having a meaning that is consistent with their meaning in the context of this specification and the relevant art and will not be interpreted in an idealized or overly formal sense unless expressly so defined herein.

When a certain example embodiment may be implemented differently, a specific process order may be performed differently from the described order. For example, two consecutively described processes may be performed substantially at the same time or performed in an order opposite to the described order.

In the accompanying drawings, variations from the illustrated shapes as a result, for example, of manufacturing techniques and/or tolerances, are to be expected. Thus, the example embodiments of the inventive concepts should not be construed as being limited to the particular shapes of regions illustrated herein but may be construed to include deviations in shapes that result, for example, from a manufacturing process. For example, an etched region illustrated as a rectangular shape may be a rounded or certain curvature shape. Thus, the regions illustrated in the figures are schematic in nature, and the shapes of the regions illustrated in the figures are intended to illustrate particular shapes of regions of devices and not intended to limit the scope of the present inventive concepts. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

While example embodiments have been shown and described above, it will be apparent to those skilled in the art that modifications and variations could be made without departing from the scope of the present disclosure, as defined by the appended claims.

1. A semiconductor device, comprising:
a peripheral circuit region on a first substrate, and comprising at least one circuit device;
a memory cell region on a second substrate that is on the first substrate, and comprising memory cells; and
a through wiring region comprising a conductive region that passes through the memory cells and is on the second substrate, and a through contact plug that passes through the conductive region and the second substrate and is configured to electrically connect the memory cell region to the at least one circuit device.

2. The semiconductor device of claim 1, wherein the through wiring region further comprises a wiring insulation layer on a side surface of the through contact plug.

3. The semiconductor device of claim 1, wherein the semiconductor device is configured to apply an erasing voltage to the second substrate through the conductive region during an erasing operation of the memory cells.

4. The semiconductor device of claim 1, wherein the memory cell region further comprises:
gate electrodes spaced apart from each other and stacked perpendicularly to an upper surface the second substrate; and
channels passing through the gate electrodes and extending perpendicularly to the upper surface of the second substrate, and
wherein the through wiring region further comprises a side insulating layer between side surfaces of the conductive region and the gate electrodes.

5. The semiconductor device of claim 4, further comprising:
a first contact plug on and electrically connected to the conductive region; and
second contact plugs on and electrically connected to the channels.

6. The semiconductor device of claim 4, wherein the second substrate has a first region in which the gate electrodes are stacked and a second region in which a first gate electrode in a lower portion of the gate electrodes extends longer than a second gate electrode in an upper portion of the gate electrodes, and
the second substrate is disposed only in the first region.

7. The semiconductor device of claim 6, further comprising dummy channels, passing through the gate electrodes in the second region,
wherein the dummy channels have a first structure different from a second structure of the channels.

8. The semiconductor device of claim 6, wherein the through wiring region is in the first region.

9. The semiconductor device of claim 1, wherein the peripheral circuit region comprises a lower wiring structure on the first substrate, and
wherein the through contact plug extends to a lower portion of the second substrate and is connected to the lower wiring structure.

10. The semiconductor device of claim 1, wherein the conductive region comprises a same material as the second substrate.

11. The semiconductor device of claim 1, wherein the conductive region comprises polycrystalline silicon.

12. (canceled)

13. The semiconductor device of claim 1, further comprising a substrate contact plug outside of the memory cells and connected to the second substrate.

14.-15. (canceled)

16. A semiconductor device, comprising:
a peripheral circuit region on a first substrate, and comprising at least one circuit device;
a memory cell region on a second substrate that is on the first substrate, and comprising gate electrodes spaced apart from each other and stacked perpendicularly to an upper surface of the second substrate, and channels passing through the gate electrodes that extend in a first direction that is perpendicular to the upper surface of the second substrate; and
a through wiring region comprising a conductive region passing through the gate electrodes and connected to the second substrate, and a through contact plug passing through the conductive region and through the second substrate and extending in the first direction.

17. The semiconductor device of claim 16, wherein the through wiring region further comprises a wiring insulation layer between the through contact plug and the conductive region.

18. The semiconductor device of claim 17, wherein the wiring insulation layer extends into the second substrate along the through contact plug.

19. (canceled)

20. The semiconductor device of claim 16, further comprising a first contact plug on and electrically connected to the conductive region.

21. The semiconductor device of claim 20, further comprising second contact plugs on and electrically connected to the channels.

22. A semiconductor device, comprising:
a first region on a first substrate, and comprising at least one first device;
a second region on a second substrate that is on the first substrate, and comprising second devices on the second substrate; and
a through wiring region comprising a through wiring structure passing through the second substrate and electrically connecting the at least one first device to the second devices and a conductive region surrounding the through wiring structure.

23. (canceled)

24. The semiconductor device of claim 22, wherein the conductive region is connected to the second substrate.

25. The semiconductor device of claim 22, wherein the semiconductor device is configured to apply an electrical signal to the second substrate through the conductive region.
